(19) United States
(12) Patent Application Publication
(10) Pub. No.: US 2008/0093528 A1
(43) Pub. Date: Apr. 24, 2008

(54) Display with a Rotary Driving Device

(76) Inventors: Cheng-Han TSAI, Taichung (TW); Fang-Fang Tai, Taichung (TW)

Correspondence Address: Dr. BANGER SHIA, 102 Lindencrest Ct., Sugar Land, TX, 77479-5201, US

(21) Appl. No.: 11/551,206

(22) Filed: Oct. 19, 2006

(51) Int. Cl. H05K 5/00; H05K 7/00

(52) U.S. Cl. 248/917; 361/681

(57) ABSTRACT

A display with a rotary driving device comprises a base, a driving device, and a display. In assembly, the driving device is mounted on the base, and then the display is fixed on a rotor of the direct drive motor of the driving device. The user can use remote control or manual touch control to set a predetermined angle that he wants the display to rotate, once the display receives signal, it will instantly instruct the direct drive motor of the driving device to rotate the rotor, so that the display will be rotated to a predetermined angle.

### BACKGROUND OF THE INVENTION

1. Field of the Invention

The present invention relates to a display, and more particularly to a display with a rotary driving device.

2. Description of the Prior Art

The use of display (such as computer screen, LCD, LCD TV, etc) has been found in various industrial fields, consumers are using various displays every day. Obviously, display brings much convenience to most of the people and is indispensable to people's daily life. However, conventional display still has some disadvantages after a long time use, because the conventional screen or display is immovably fixed to the base, that's called integral type display. If the user wants to angularly adjust the position of the screen or the display, for example, to turn the display or the screen a certain angle to the rear audience or the side audience, he has to rotate it by hand. Each angular adjustment of the display must be done by hand, so it is really inconvenient. Afterwards, to overcome the abovementioned inconvenience, micro motor was used to rotate the display, achieving an angular adjustment. However, the micro motor is difficult to control and to stop it precisely at a predetermined position, the motor usually rotates neither excessively nor deficiently.

The present invention has arisen to mitigate and/or obviate the afore-described disadvantages.

### SUMMARY OF THE INVENTION

The primary objective of the present invention is to provide a display with a rotary driving device, in the structure of this invention, the direct drive motor of the driving device is directly used on the display, so that the user can use wireless control method or manual touch control to rotate the display or the screen. Therefore, the control of the display is quick and easy.

The secondary objective of the present invention is to provide a display with a rotary driving device, since the display additionally has a function of controlling the angle adjustment of the display or the screen by wireless control or manual touch control, thus improving the product's additional value.

The primary objective of the present invention is to provide a display with a rotary driving device, in the structure of this invention, the direct drive motor of the driving device is directly used on the display, so that the user can use wireless control method or manual touch control to rotate the display or the screen. Therefore, the control of the display is quick and easy.

The secondary objective of the present invention is to provide a display with a rotary driving device, since the display additionally has a function of controlling the angle adjustment of the display or the screen by wireless control or manual touch control, thus improving the product's additional value.

A display with a rotary driving device in accordance with the present invention comprises:

a base;

a driving device mounted on the base, including a direct drive motor, the direct drive motor serves to rotate a rotor a predetermined angle; and

a display fixed on the rotor of the direct drive motor of the driving device;

wherein the user can use remote control or manual touch control to set a predetermined angle that he wants the display to rotate, once the display receives signal, it will instantly instruct the direct drive motor of the driving device to perform a rotary motion, so that the display will be driven to rotate a predetermined angle.

### BRIEF DESCRIPTION OF THE DRAWINGS

FIG. 1 is an exploded view of a display with a rotary driving device in accordance with the present invention;

FIG. 2 is an assembly view of a display with a rotary driving device in accordance with the present invention;

FIG. 3 is an exploded view of a driving device in accordance with the present invention;

FIG. 4 is an assembly view in accordance with the present invention of showing that the display with a rotary driving device is used on a computer display; and

FIG. 5 is an assembly view in accordance with the present invention of showing that the display with a rotary driving device is used on a computer display.

### DETAILED DESCRIPTION OF THE PREFERRED EMBODIMENTS

The present invention will be more clear from the following description when viewed together with the accompanying drawings, which show, for purpose of illustrations only, the preferred embodiment in accordance with the present invention.

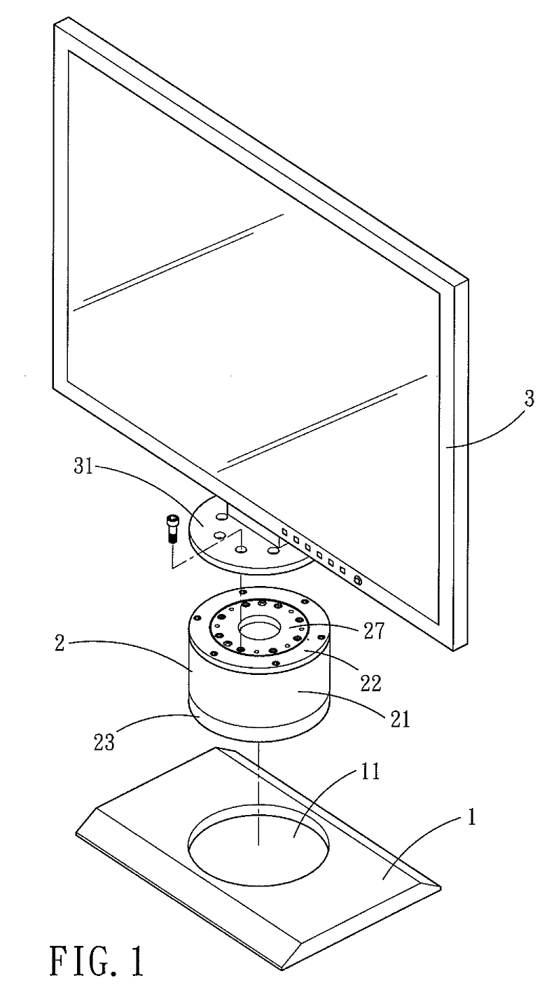

Referring to FIGS. 1-4, a display with a rotary driving dive in accordance with a preferred embodiment is shown and comprises: a base 1, a driving device 2, and a display 3.

The base 1 is the same as a base of a conventional base and is provided for positioning the display, in the base 1 of this embodiment is particularly formed a groove 11.

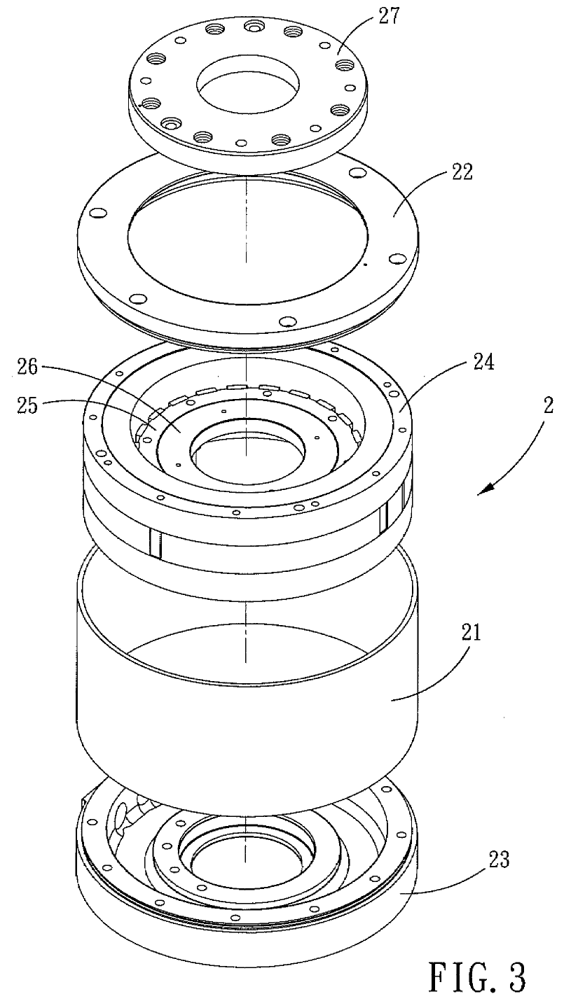

The driving device 2 is disposed in the groove 11 and includes a direct drive motor (also called torque motor), as shown in FIG. 3. The driving device 2 is provided with a stator 24 and a rotor 25 that are disposed in a spaced defined a housing 21, a cover 22 and a seat 23. The stator 24 is fixed on the seat 23, on the inner periphery of the rotor 25 is disposed a bearing 26, and on the top surface of the rotor 25 is fixed a fixing seat 27. With the aid of the bearing 26, the rotor 25 and the fixing seat 27 will be driven by the magnetic field of the stator 24 to rotate around the inner periphery of the stator 24. By such arrangements, the direct drive motor can make the rotor 25 rotate a predetermined angle.

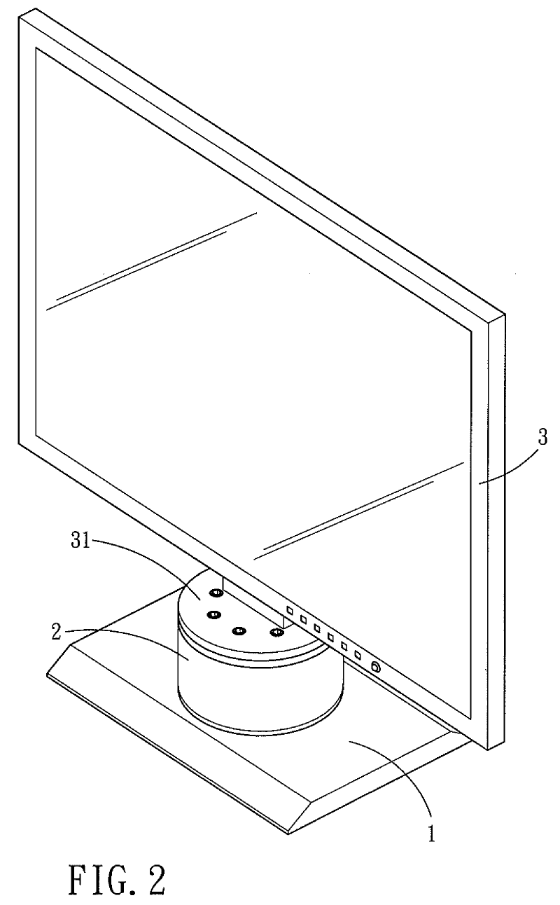

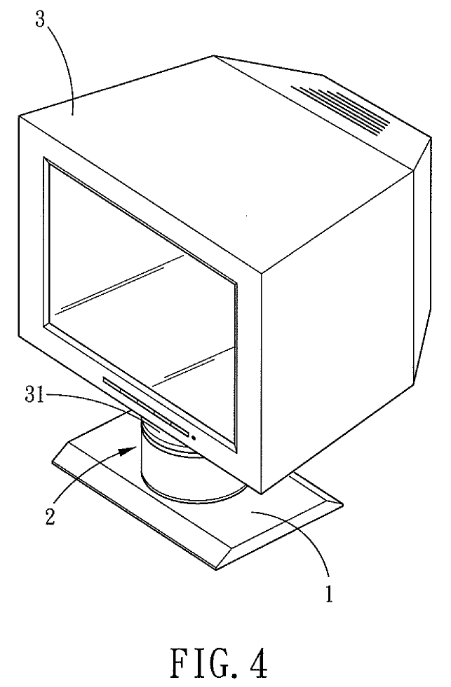

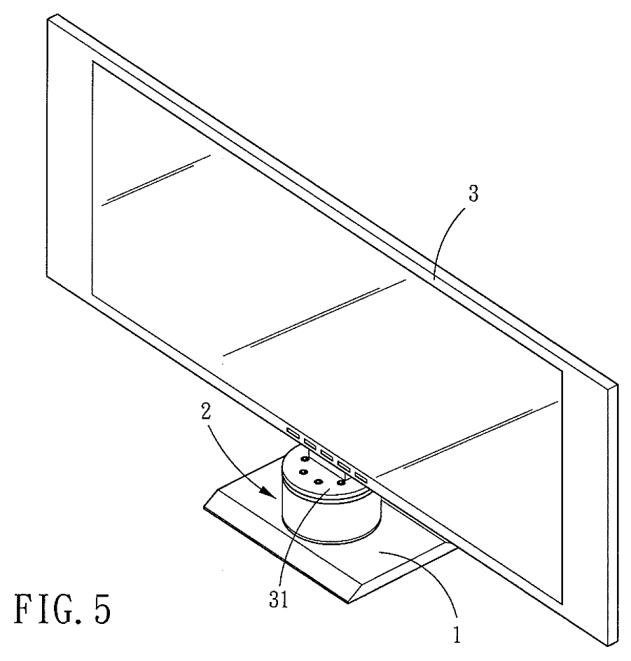

The display 3 can be a computer display (as shown in FIG. 4), a LCD display (as shown in FIG. 2), a LCD TV (as shown in FIG. 5), and etc. For easy assembly, a connecting board 31 can be formed at the bottom of the display 3, so as to fix the display 3 to the fixing seat 27. By such arrangements, the driving device 2 can be stably assembled to the display 3.

For a better understanding of the embodiment, its operation and function, reference should be made to the respective figures again. When the user wants to rotate the display 3 to a predetermined angle, he can use a remote control (not shown) or the display to set a predetermined angle that he wants the display 3 to rotate, by using wireless control or manual control. Once the display 3 receives the signal, it will instantly instruct the direct motor of the driving device 2 to rotate the rotor 25 a predetermined angle, as a result, the display 3 assembled to the rotor 25 will also be rotated the predetermined angle. Therefore, the control of the display 3 is quick and easy.

To summarize, in the structure of this invention, the direct drive motor of the driving device is directly used on the display, so that the user can use wireless control method or manual touch control to rotate the display or the screen. Therefore, the control of the display is quick and easy.

While we have shown and described various embodiments in accordance with the present invention, it is clear to those skilled in the art that further embodiments may be made without departing from the scope of the present invention.

What is claimed is:

1. A display with a rotary driving device, comprising:
a base;
a driving device mounted on the base, including a direct drive motor, the direct drive motor serves to rotate a rotor a predetermined angle; and
a display fixed on the rotor of the direct drive motor of the driving device;
wherein the user can use remote control or manual touch control to set a predetermined angle that he wants the display to rotate, once the display receives signal, it will instantly instruct the direct drive motor of the driving device to perform a rotary motion, so that the display will be driven to rotate a predetermined angle.

2. The display with a rotary driving device as claimed in claim 1, wherein a groove is formed in the base, and the driving device is disposed in the groove.

3. The display with a rotary driving device as claimed in claim 1, wherein a connecting board is formed at a bottom of the display, so as to fix the display to a fixing seat of the rotor, by such arrangements, the driving device is stably assembled to the display.
